(19) United States
(12) Patent Application Publication
(10) Pub. No.: US 2006/0001064 A1
(43) Pub. Date: Jan. 5, 2006

(54) Methods for the lithographic deposition of ferroelectric materials

(76) Inventors: Ross H. Hill, Coquitlam (CA); Hyung-Ho Park, Seoul (KR)

Correspondence Address: MORGAN, LEWIS & BOCKIUS LLP;COUNSELORS AT LAW, 2 Palo Alto Square, Suite 700, 3000 El Camino Real, Palo Alto, CA, 94306, US

(21) Appl. No.: 11/107,491

(22) Filed: Apr. 14, 2005

Related U.S. Application Data
(63) Continuation-in-part of application No. 10/716,838, filed on Nov. 18, 2003.
Application No. 10/716,838 is a continuation-in-part of application No. 10/263,701, filed on Oct. 4, 2002, now Pat. No. 6,849,305.
Application No. 10/263,701 is a continuation-in-part of application No. 10/037,176, filed on Nov. 8, 2001, now Pat. No. 6,660,632.
Application No. 10/037,176 is a division of application No. 09/561,744, filed on Apr. 28, 2000, now Pat. No. 6,348,239.
(60) Provisional application No. 60/327,009, filed on Oct. 5, 2001.

(51) Int. Cl. H01L 21/00; H01L 29/76

(52) U.S. Cl. 257/295; 438/3

(57) ABSTRACT

The invention is directed toward a photoresist-free method for depositing films comprising ferroelectric materials from metal complexes. More specifically, the method involves applying an amorphous film of a metal or metal oxide complex to a substrate. The metal complexes have the general formula MₐM′_{b}L_{c}L′_{d}, wherein M and M′ are independently selected from the group consisting of Li, Al, Si, Ti, V, Cr, Mn, Fe, Ni, Co, Cu, Zn, Sr, Y, Zr, Nb, Mo, Ru, Rh, Pd, Ag, In, Sn, Ba, La, Pr, Sm, Eu, Hf, Ta, W, Re, Os, Ir, Pt, Au, Pb, Th, U, Sb, As, Ce, and Mg, and L and L′ are preferentially a ligand selected from the group consisting of acac, carboxylato, alkoxy, azide, carbonyl, nitrato, amine, halide, nitro, and mixtures thereof. These films, upon, for example, light or electron beam irradiation, may be converted to the metal or its oxides. By using either directed light or electron beams, this may lead to a patterned ferroelectric film in a single step.

This application is a continuation-in-part of application Ser. No. 10/716,838, filed Nov. 18, 2003, which is a continuation-in-part of application Ser. No. 10/263,701, filed Oct. 4, 2002, now U.S. Pat. No. 6,849,305, which is a continuation-in-part of application Ser. No. 10/037,176, filed Nov. 8, 2001, now U.S. Pat. No. 6,660,632, which is a division of application Ser. No. 09/561,744, filed Apr. 28, 2000, now U.S. Pat. No. 6,348,239, which claims the benefit of Provisional Application No. 60/327,009, filed Oct. 5, 2001. Each of the foregoing applications and patents are incorporated by reference herein in their entireties.

### BACKGROUND OF THE INVENTION

1. Field of the Invention

This invention relates to methods for fabrication of patterned films of metal-containing compounds on a substrate. More particularly, the present invention relates to the deposition of ferroelectric films for use in capacitors, gate oxides, memory devices, and other devices.

2. Description of the Related Art

Ferroelectric materials possess a high dielectric constant. This makes them valuable to the electronics industry as materials for capacitors or to be used as gate oxides, for instance. They also may possess a strong remnant polarization. This property makes them useful for memory applications, such as FeRAM. Accordingly, there is much interest in the development of methods of achieving the deposition of metals and the patterned deposition of metals or their oxides so as to form ferroelectric films on various substrates.

The semiconductor and packaging industries, among others, utilize conventional processes to form thin metal and metal oxide films, including ferroelectric materials, in their products. Examples of such processes include evaporation, sputter deposition or sputtering, chemical vapor deposition (“CVD”) and thermal oxidation.

Evaporation is a process whereby a material to be deposited is heated near the substrate on which deposition is desired. Normally conducted under vacuum conditions, the material to be deposited volatilizes and subsequently condenses on the substrate, resulting in a blanket or unpatterned film on the substrate. This method has several disadvantages, including, for example, the requirement of heating the desired film material to high temperatures and the need for high vacuum conditions.

Sputtering is a technique similar to evaporation in which the process of transferring the material for deposition into the vapor phase is assisted by bombarding that material with incident atoms of sufficient kinetic energy such that particles of the material are dislodged into the vapor phase and subsequently condense onto the substrate. Sputtering suffers from the same disadvantages as evaporation and, additionally, requires equipment and consumables capable of generating incident particles of sufficient kinetic energy to dislodge particles of the deposition material.

CVD is similar to evaporation and sputtering but further requires that the particles being deposited onto the substrate undergo a chemical reaction during the deposition process in order to form a film on the substrate. While the requirement for a chemical reaction distinguishes CVD from evaporation and sputtering, the CVD method still demands the use of sophisticated equipment and extreme conditions of temperature and pressure during film deposition.

In thermal oxidation a blanket layer of an oxidized film on a substrate is produced by oxidizing an unoxidized layer that had previously been deposited on the substrate. However, thermal oxidation generally employs extreme temperature conditions and an oxygen atmosphere.

Several existing film deposition methods may begin under conditions of ambient temperature and pressure, including sol-gel and other spin-on methods, but these methods do not fully eliminate the need for heating. In these methods, a solution containing precursor particles that may be subsequently converted to the desired film composition is applied to the substrate. Application of this solution may be accomplished through spin-coating or spin-casting, where the substrate is rotated around an axis while the solution is dropped onto the middle of the substrate. However, following the ambient temperature application, the coated substrate must still be subjected to a subsequent high-temperature heating step to convert the precursor film into a film of the desired material. Thus, these methods do not allow for direct imaging at ambient temperature to form patterns of the amorphous film. Instead, they result in blanket, unpatterned films of the desired material and still require the application of high temperatures to effect conversion of the deposited film to the desired material.

Furthermore, when a film is created by the above methods it is amorphous and must be converted to a crystalline or semi-crystalline state if it is to possess ferroelectric properties. This is accomplished through annealing. The metal film must be heated to very high temperatures, often as high as 500° C., to create the desired long-range order. This is a time-consuming and expensive step.

Even further, once film deposition is accomplished via one of these deposition methods, a separate patterning step is required if a patterned film is desired. In one method of patterning blanket films, the blanket film is coated (either by spin coating or other solution-based coating method or by application of a photosensitive dry film) with a photosensitive coating. This photosensitive layer is selectively exposed to light of a specific wavelength through a mask. The exposure changes the solubility of the exposed areas of the photosensitive layer in such a manner that either the exposed or unexposed areas may be selectively removed by use of a developing solution. The remaining material is then used as a pattern transfer medium, or mask, to an etching medium that patterns the film of the desired material. Following this etch step, the remaining (formerly photosensitive) material is removed, and any by-products generated during the etching process are cleaned away if necessary.

In another method of forming patterned films on a substrate, a photosensitive material may be patterned as described above. Following patterning, a conformal blanket of the desired material may be deposited on top of the patterned (formerly photosensitive) material. The substrate with the patterned material and the blanket film of the desired material is then exposed to a treatment that attacks the formerly photosensitive material. This treatment removes the remaining formerly photosensitive material and with it portions of the blanket film of desired material on top. In this fashion a patterned film of the desired material results; no etching step is necessary in this “liftoff” process. However, the use of an intermediate pattern transfer medium (photosensitive material) is still required, which is a disadvantage. It is also known that the “liftoff” method has limitations with regard to the resolution (minimum size) that may be realized by the pattern of the desired material. This limitation restricts the usefulness of this method.

In yet another method of forming patterned films, a blanket film of desired material may be deposited by, for example, one of the methods described above, onto a substrate that has previously been patterned by, for example, an etching process. The blanket film is deposited in such a way that its thickness fills in and completely covers the existing pattern in the substrate. A portion of the blanket film is then isotropically removed until the remaining desired material and the top of the previously patterned substrate are at the same height. Thus, the desired material exists in a pattern embedded in the previously patterned substrate. The isotropic removal of the desired material may be accomplished via etching or through a process known as chemical mechanical planarization (“CMP”), which involves the use of a slurry of particles in conjunction with a chemical agent to remove substantial quantities of the desired material through a combination of chemical and mechanical action, leaving behid the desired material in the patterned substrate. This method of forming a patterned film demands the use of expensive and complicated planarization equipment and extra consumable materials including planarization pads, slurries and chemical agents. In addition, the use of small slurry particles demands that these particles be subsequently removed from the planarized surface, invoking extra processing steps.

These conventional processes for forming metal and metal oxide films are not optimal because, for example, they each require costly equipment, are time consuming, require the use of high temperatures to achieve the desired result, and result in blanket, unpatterned films where, if patterning is needed, further patterning steps are required. Accordingly, there is a need for a method of making a patterned film in fewer processing steps that are less time consuming and that require less costly equipment. In particular, there is a need for a method for making a patterned film that comprises ferroelectric materials.

### SUMMARY OF THE INVENTION

The present invention provides a process for making a patterned film of ferroelectric materials. In one embodiment of the present invention, a ferroelectric film is deposited on a substrate by selecting at least one precursor, forming a layer comprising the precursor atop a substrate, and irradiating at least a portion of the precursor layer, thereby forming a ferroelectric film on the substrate. No high-temperature heating is necessary, thus eliminating a time-consuming and costly process step.

The processes of the present invention are useful in the deposition of films containing ferroelectric materials. These processes are advantageous over prior art deposition methods because they avoid the expense and time associated with the additional processing steps required in the prior art, such as masking, exposure and removal, CMP removal of excess material and high temperature processing to form films with ferroelectric properties. The present invention has the additional benefit of eliminating the need to store additional chemical reagents necessary to accomplish the prior art methods, thus improving cleanroom storage and decreasing the possibility of contamination. Yet another benefit of the current invention is that it eliminates the need for photoresist in patterning electronic materials. This reduces the likelihood of device contamination from removal of the organic photoresist material in subsequent processing steps following patterning. The present invention allows for advantages unavailable with other ferroelectric film deposition and formation methods. As a result, it presents the user with a greater ability to control and manipulate the characteristics of the resulting film to suit the desired application. Such films may be of use in a variety of applications, including, but not limited to microelectronic fabrication, particularly where the high dielectric constant and remnant polarization characteristic of ferroelectric materials are applicable. Therefore, the present invention is useful in a broad spectrum of applications.

### BRIEF DESCRIPTION OF THE DRAWINGS

FIG. 1 is a process flow diagram according to an embodiment of the present invention;

FIG. 2A is a schematic cross-sectional view of a substrate covered with precursor material;

FIG. 2B is a schematic cross-sectional view of a substrate covered with converted precursor material;

FIG. 2C is a schematic cross-sectional view of a substrate covered with precursor material being directly patterned using a maskless process;

FIG. 2D is a schematic cross-sectional view of a substrate covered with precursor material being converted through blanket exposure to an energy source; and

FIG. 3 illustrates room temperature deposition of a pattered ferroelectric film according to one embodiment of the present invention.

### DETAILED DESCRIPTION OF THE PREFERRED EMBODIMENT

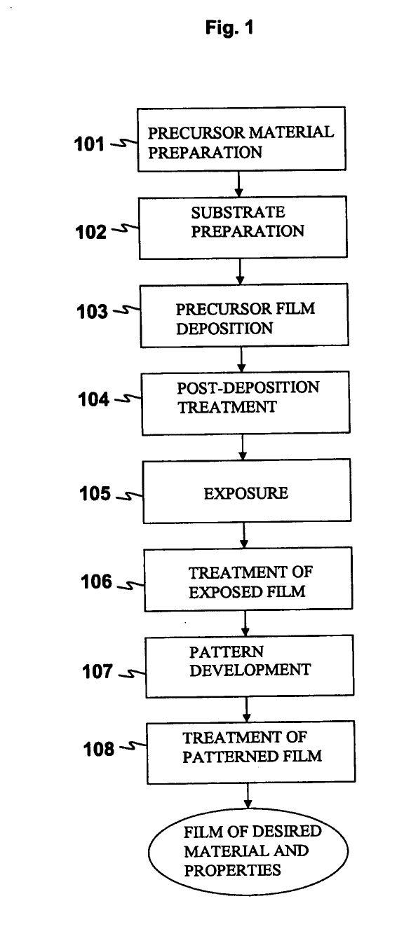

FIG. 1 is a process flow diagram according to one embodiment of the present invention. FIG. 1 provides an overview of one embodiment of a process that may be followed to obtain a film of desired material with optimized properties for a particular application. Many of these steps are fully optional, based on the ultimate application of the film. The present invention is also not limited to these steps and may include other steps, based on the ultimate application of the film.

Step 101 of FIG. 1 involves choosing and preparing a precursor material. The precursor material may be a single chemical species, or a mixture of different chemical species, depending on the final film composition. The present invention will typically be drawn toward the formation of films exhibiting ferroelectric behavior, and the choice of starting precursor materials will often, but not exclusively, be based on known crystalline ferroelectric materials. Examples of known crystalline ferroelectric compounds that are amenable to this method include, but are not limited to, BaₓSr_{y}Ti_{z}O₃ (“BST”) and PbₓZr_{y}Ti_{z}O₃ (“PZT”). However, it is recognized that the formation of films containing a mixture of such species with other metallic or semi-metallic species may be desirable in some embodiments, and nothing in this document should be read to preclude the formation of such films. Also, nothing in the present invention limits its application to known crystalline ferroelectric materials. Furthermore, it is important to recognize that the choice of chemical species that make up the precursor material is subject to processing constraints associated with the present invention. In particular, the precursor material further comprises molecules specifically designed for their ability to coat the substrate in a uniform manner, resulting in films of high optical quality that possess, in the case of the present process, photosensitive properties. As discussed further below, such properties in deposited films are most often associated with the ligand portion of the precursor material.

The precursor material comprises one or more metal complexes of the formula MₐL_{c} comprising at least one metal (“M”), where a is an integer that is at least 1, and at least one suitable ligand (“L”) or ligands, where c is an integer that is at least 1, are envisioned by this invention. Furthermore, the metal complexes are not restricted to those with one metal Mₐ and one ligand L_{c}. Metal complexes may also comprise the structure MₐL_{c}L_{d}, in which L_{c} and L_{d} are different chemical species. Even further, compounds of the formula MₐM_{b}L_{c}L_{d} are used to facilitate the formation of mixed films such as BaTiO₃ films. Suitable precursors are also described in U.S. Pat. No. 6,566,276 to Maloney, et at., entitled “Method of Making Electronic Materials,” which is incorporated by reference herein in its entirety.

If a plurality of metals is used, all of the metal atoms may be identical; all may be different atoms and/or have different valences, e.g., BaNa or Fe(II)Fe(III); or some may be identical while others may be different atoms and/or have different valences, e.g., Ba₂ Fe(II) Fe(III). In any case, each additional metal M may be an alkali or alkaline earth, for example, Ba or Li; a transition metal, for example, Cr or Ni; a main group metal, for example, Al or Sn; or an actinide, for example, U or Th. Preferably, each metal is independently selected from Li, Al, Si, Ti, V, Cr, Mn, Fe, Ni, Co, Cu, Zn, Sr, Y, Zr, Nb, Mo, Ru, Rh, Pd, Ag, In, Sn, Ba, La, Pr, Sm, Eu, Hf, Ta, W, Re, Os, Ir, Pt, Au, Pb, Th, U, Sb, As, Ce, and Mg.

Similarly, there is a wide variety of ligands that may be used for the present invention. The choice of ligand is important because it influences the nature of both the precursor molecule and the final deposited film. Ligand L is preferably chosen so that the precursor material has the following properties: (1) it can be deposited as an amorphous film on a substrate and will remain amorphous until a subsequent processing step; (2) the amorphous film is stable or at least metastable; (3) upon absorbing energy, for example a photon of the required energy, the film can be transformed into a different metal-containing material through a chemical reaction; and (4) any byproducts of the energy-induced chemical reaction should be removable, i.e., should be sufficiently volatile so as to be removable from the film. In addition, for certain embodiments of the present invention it may be necessary to use a mixture of ligands. If a plurality of ligands is used, all of the ligands may be identical, all may be different, or some may be identical while others may be different.

The amorphous quality of the film is desirable for at least two reasons. The deposited film of precursor material should be amorphous or at least substantially amorphous to ensure that the film will have the desired isotropic optical properties. Additionally, an amorphous film provides the additional advantage of minimizing recombination reactions, which occur in a more crystalline environment. Avoiding such reactions leads to a higher quantum yield for photoreactions within the film. To form an amorphous film, the complex should possess a low polarity and low intermolecular forces. As organic groups usually have low intermolecular forces, ligands having organic groups at their outer peripheries typically are satisfactory. Furthermore, to make the metal complex resistant to crystallization, ligand(s) L preferably are such that the complex is of lower symmetry, which can, in certain embodiments, slow the crystallization rate. Alternatively, one may use unresolved chiral ligands in the metal complex to slow crystallization. For example, if L is racemic 2-ethylhexanoate, the resulting metal precursor is a mixture of metal complexes that differ in their three-dimensional structure, often existing as enantiomers, diastereomers, or a mixture of both. The size and shapes of organic portions of the ligands may be selected to optimize film stability and to adjust the thickness of film that will be deposited by the selected film deposition process.

The tendency of an amorphous film to remain amorphous may also be enhanced by forming the film from a complex that has several different ligands attached to each metal atom. Such metal complexes have several isomeric forms. For example, the reaction of CH₃HNCH₂CH₂NHCH₃ with a mixture of a nickel(II) salt and KNCS leads to the production of a mixture of isomers. The chemical properties of the different isomers are known not to differ significantly; however, the presence of several isomers in the film impairs crystallization of the complex in the film.

Further on the subject of amorphous films, it is important to recognize that amorphous films are distinct from polycrystalline and crystalline films. In addition, different amorphous films formed by different film-forming methods may be different from one another. Through judicious choice of process parameters, the different properties of different amorphous films formed by different methods can be controlled and engender specific chemical, physical and mechanical properties that are useful in particular applications, for example, as a layer(s) in a semiconductor device and/or in their fabrication

Another requirement of the precursor material is the complex must also be stable, or at least metastable, in that it will not rapidly and spontaneously decompose under process conditions. The stability of complexes of a given metal may depend, for example, upon the oxidation state of the metal in the complex. For instance, Ni(0) complexes are known generally to be unstable in air while Ni(II) complexes are often air-stable. Consequently, a process for depositing Ni-based films that includes processing steps in an air atmosphere should include a Ni(II) complex in preference to a Ni(0) complex.

As discussed below, partial conversion and conversion result from a chemical reaction within the film that changes substantially unconverted or partially converted regions into a desired converted material. Ideally, at least one ligand should be reactive and be attached to the complex by a bond that is cleaved when the complex is raised to an excited state by the influence of the energy applied to convert the precursor material. If the energy applied is light energy, the chemical reaction of step (3) is known as a photochemical reaction. Photochemical reactions initiated by light, or more preferably, by ultraviolet light, are the most preferred form of applied energy. To make such photochemical step(s) in the process efficient, it is highly preferable that the intermediate product produced when the reactive group is severed be unstable and spontaneously convert to the desired new material and volatile byproduct(s).

Exemplary metal complexes, and their metal and ligand components, are described in U.S. Pat. No. 5,534,312 to Hill, et. al., which is incorporated by reference herein in its entirety. Preferred metal complex precursors include ligands that meet the above criteria. More preferably, the ligands are selected from the group consisting of acetylacetonate (also known as “acac” or 2,4-pentanedione) and its anions; substituted acetylacetonate, 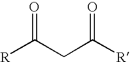
and its anions; acetonylacetone (also known as 2,5-hexanedione) and its anions; substituted acetonylacetone, 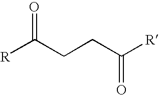
and its anions; dialkyldithiocarbamates, 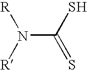
and their anions; carboxylic acids, 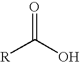
such as hexanoic acid where R=CH₃(CH₂)₄; carboxylates, 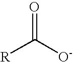
such as hexanoate where R=CH₃(CH₂)₄; pyridine and/or substituted pyridines, 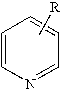
azide, i.e., N₃⁻; amines, e.g., RNH₂; diamines, e.g., H₂NRNH₂; arsines, 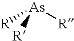
diarsines, 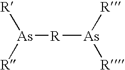
phosphines, 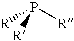
diphosphines, 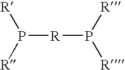
arenes, 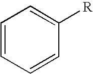
hydroxy, i.e., OH³¹ ; alkoxy ligands, e.g., RO⁻; ligands such as (C₂H₅)₂NCH₂CH₂O—; alkyl ligands, e.g., R⁻; and aryl ligands, and mixtures thereof, where each R, R′, R″, R′″, and R″″ is independently selected from organic groups and, preferably, is independently selected from alkyl, alkenyl, aralkyl and aralkenyl groups.

As used herein, the term “alkyl” refers to a straight or branched hydrocarbon chain. As used herein, the phrase straight-chain or branched-chain hydrocarbon chain means any substituted or unsubstituted acyclic carbon-containing compounds, including alkanes, alkenes and alkynes. Examples of alkyl groups include lower alkyl, for example, methyl, ethyl, n-propyl, iso-propyl, n-butyl, iso-butyl, tert-butyl or iso-hexyl; upper alkyl, for example, n-heptyl, -octyl, iso-octyl, nonyl, decyl, and the like; lower alkylene, for example, ethylene, propylene, propylyne, butylene, butadiene, pentene, n-hexene or iso-hexene; and upper alkylene, for example, n-heptene, n-octene, iso-octene, nonene, decene and the like. The ordinary skilled artisan is familiar with numerous straight, i.e., linear, and branched alkyl groups, which are within the scope of the present invention. In addition, such alkyl groups may also contain various substituents in which one or more hydrogen atoms is replaced by a functional group or an in-chain functional group.

As used herein, the term “alkenyl” refers to a straight or branched hydrocarbon chain where at least one of the carbon-carbon linkages is a carbon-carbon double bond. As used herein, the term “aralkyl” refers to an alkyl group which is terminally substituted with at least one aryl group, e.g., benzyl. As used herein, the term “aralkenyl” refers to an alkenyl group which is terminally substituted with at least one aryl group. As used herein, the term “aryl” refers to a hydrocarbon ring bearing a system of conjugated double bonds, often comprising at least six π (pi) electrons. Examples of aryl groups include, but are not limited to, phenyl, naphthyl, anisyl, toluyl, xylenyl and the like.

The term “functional group” in the context of the present invention broadly refers to a moiety possessing in-chain, pendant and/or terminal functionality, as understood by those persons of ordinary skill in the relevant art. Examples of in-chain functional groups include, for example, ethers, esters, amides, urethanes and their thio-derivatives, i.e., where at least one oxygen atom is replaced by a sulfur atom. Examples of pendant and/or terminal functional groups include, for example, halogens, such as fluorine and chlorine; hydrogen-containing groups such as hydroxyl, amino, carboxyl, thio and amido, isocyanato, cyano, and epoxy; and ethylenically unsaturated groups such as allyl, acryloyl and methacryloyl, and maleate and maleimido.

To enhance the desired photochemical characteristics, including the tendency of the products of the photochemical reaction to spontaneously thermally decompose, ligands comprising and/or selected from one or more of the following groups may be used alone or in combination with the above-listed ligands: oxo, O₂⁻; oxalato, 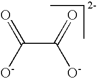
halide; hydrogen; hydride, i.e., H⁻; dihydride, i.e., H₂; hydroxy; cyano, i.e., CN⁻; carbonyl; nitro, i.e., NO₂; nitrito, i.e., NO₂⁻; nitrate, i.e, NO₃²⁻; nitrato, i.e., NO₃⁻; nitrosyl, i.e., NO; ethylene; acetylenes,
R≡R′
thiocyanato, i.e., SCN⁻; isothiocyanato, i.e., NCS⁻; aquo, i.e., H₂O; azides; carbonato, i.e., CO₃⁻²; amine; and thiocarbonyl, where each R and R′ is independently selected from organic groups and, preferably, is independently selected from alkyl, alkenyl, aralkyl and aralkenyl groups. Even more preferably, each ligand is independently selected from acac, carboxylates, alkoxy, oxalato, azide, carbonyl, nitro, nitrato, amine, halogen and their anions.

It should be appreciated that the choice of precursor material may have a significant influence on the properties of the desired film that is not readily predictable. For example, two precursors ML and ML′, each consisting of metal M and one of two different ligands L or L′, might be expected to form films of the desired material that are identical because, for example, the portions of the ligands that differ from each other would be removed during conversion of the precursor into a metal film. In fact, the supposedly identical film products of these two similar reactants may differ significantly in their properties. Examples of properties that may be affected in this process include the dielectric constant and the presence/absence of any secondary or tertiary structure in the film. Possible reasons for this difference may relate to the rate of formation of the amorphous material and the ability of the photo-ejected ligand to remove energy from the photo-produced film of desired material. The presence of ligand fragments during an exposure process may also affect the film forming process, influencing such phenomena as diffusion properties of the film, nucleation, and crystal growth.

Further, the choice of the precursor material in film formation and photochemical exposure can substantially influence further reactivity of the film of the desired material with, for example, gaseous constituents of the atmosphere in which the desired film is formed. This could influence, for example, the rate of oxidation of the deposited film where either a high or low rate could be an advantage depending upon the desired product. Additionally, it is recognized that the effect of the precursor material upon the healing ability of the film, i.e., its ability to minimize crazing, and the shrinkage or densification of the film may be substantially influenced by the choice of precursors that would otherwise be seen to yield identical results by one skilled in the art.

In step 102 of FIG. 1, which is fully optional, a substrate is prepared for deposition of the precursor film. The nature of the substrate to which the precursor is applied is not critical for the process, although it may affect the method of deposition of the precursor film and the solvent for the deposition, if one is used. Substrates may include, but are not limited to, simple salts, such as CaF₂; semiconductor surfaces, including silicon; compound semiconductors, including silicon germanium and III-V and II-VI semiconductors; printed and/or laminated circuit board substrates; metals; ceramics; and glasses. Silicon wafers, ceramic substrates, and printed circuit boards have been used extensively. Prior to its use in the present process, other types of substrate preparation known in the art may be performed, such as cleaning the substrate, the deposition of an adhesion promoter, and/or the use of a reactive layer. In addition, the substrate may be coated with single or multiple layers, such as dielectric layers, photoresist, polyimide, metal oxides, thermal oxides, conductive materials, insulating materials, ferroelectric materials or other materials used in the construction of electronic devices. If no substrate preparation is required prior to deposition, processing should continue directly from step 101 to step 103.

In step 103 of FIG. 1, the precursor film is deposited. The method of application of the precursor or the precursor solution may be chosen depending on the substrate and the intended application. Some examples of useful coating methods that may be used include spin, spray, dip and roller coating, stamping, meniscus, and various inking approaches, e.g., inkjet-type approaches. Variables in the coating process may be chosen to control the thickness and uniformity of the deposited film, to minimize edge effects and the formation of voids or pinholes in the film, and to ensure that no more than the required volume of precursor or precursor solution is consumed during the coating process. Optimized application of the precursor film may desirably yield very smooth films.

The precursor material may be applied to the substrate alone or preferably as a precursor solution comprising the precursor material dissolved in a solvent or solvents. The use of solvent facilitates the application of the precursor material to the substrate by a variety of means, such as by spin or spray application of the solution to the substrate. The solvent may be chosen based on several criteria, individually or in combination, including the ability of the solvent to dissolve the precursor, the inertness of the solvent relative to the precursor, the viscosity of the solvent, the solubility of oxygen or other gases in the solvent, the UV, visible, and/or infra-red absorption spectra of the solvent, the absorption cross-section of the solvent with respect to electron and/or ion beams, the volatility of the solvent, the ability of the solvent to diffuse through a subsequently formed film, the purity of the solvent with respect to the presence of different solvent isomers, the purity of the solvent with respect to the presence of metal ions, the thermal stability of the solvent, the ability of the solvent to influence defect or nucleation sites in a subsequently formed film, and environmental considerations concerning the solvent. Exemplary solvents include the alkanes, such as hexanes; the ketones, such as methyl isobutyl ketone (“MIBK”) and methyl ethyl ketone (“MEK”); and propylene glycol monomethyl ether acetate (“PGMEA”).

The concentration of the precursor material in the solution may be varied over a wide range and may be chosen, such that the properties of the precursor film, including its thickness and/or sensitivity to irradiation by light or particle beams, are appropriate for the desired application.

Finally, chemical additives are optionally used with the precursor material, if applied alone, or in the precursor solution. These may be present for any or several of the following reasons: to control the photosensitivity of a subsequently deposited precursor or film, to aid in the ability to deposit uniform, defect-free films onto a substrate, to modify the viscosity of the solution, to enhance the rate of film formation, to aid in preventing film cracking during subsequent exposure of the deposited film, to modify other bulk properties of the solution, and to modify in important ways the properties of the film of the desired material. The additives are chosen according to these criteria in addition to those criteria employed when choosing a suitable solvent. It is preferable that the precursor or the precursor solution be substantially free of particulate contamination so as to enhance its film-forming properties.

In some embodiments, no further processing of the precursor material is required. More often, however, processing will continue with either post-deposition treatment 104 or proceed directly to the exposure stage 105.

In step 104 of FIG. 1, following deposition, an optional post-deposition treatment may be used. The deposited film may, for instance, optionally be subjected to a baking or vacuum step where any residual solvent present in the deposited film may be driven off. If such a baking step is employed, it is, of course, important to use the minimum amount of heat necessary to drive off the solvent. Application of excessive heat to the precursor material may cause the film to decompose through thermal decomposition.

In step 105 of FIG. 1, the deposited film is subjected to an energy source such that the precursor is at least partially converted though photolytic conversion. The entire film, or selected regions of the deposited precursor film, may be exposed to a source of energy. The energy source may be, e.g., a light source of a specific wavelength, a coherent light source of a specific wavelength or wavelengths, a broadband light source, an electron beam (“e-beam”) source, or an ion beam source. Light in the wavelength range of from about 150 to about 600 nm may be used.

Without being bound by any particular theory, it is believed that there are several mechanisms by which a suitable photochemical reaction may occur to cause conversion of the precursor material. Some examples of suitable reaction mechanisms which may be operable, individually or in combination, according to the invention are as follows: (a) absorption of a photon may place the complex in a ligand to metal charge transfer excited state in which a metal-to-ligand bond in the metal complex is unstable, the bond breaks and the remaining parts of the complex spontaneously decompose, (b) absorption of a photon may place the complex in a metal-to-ligand charge transfer excited state in which a metal-to-ligand bond in the complex is unstable, the bond breaks and the remaining parts of the complex spontaneously decompose, (c) absorption of a photon may place the complex in a d-d excited state in which a metal-to-ligand bond in the complex is unstable, the bond breaks and the remaining parts of the complex spontaneously decompose, (d) absorption of a photon may place the complex in an intramolecular charge transfer excited state in which a metal-to-ligand bond in the complex is unstable, the bond breaks and the remaining parts of the complex spontaneously decompose, (e) absorption of a photon may place at least one ligand of the complex in a localized ligand excited state, a bond between the excited ligand and the complex is unstable, the bond breaks and the remaining parts of the complex spontaneously decompose, (f) absorption of a photon may place the complex in an intramolecular charge transfer excited state such that at least one ligand of the complex is unstable and decomposes, then the remaining parts of the complex are unstable and spontaneously decompose, (g) absorption of a photon may place at least one ligand of the complex in a localized ligand excited state wherein the excited ligand is unstable and decomposes, then the remaining parts of the complex are unstable and spontaneously decompose, and (h) absorption of a photon may place the complex in a metal-to-ligand charge transfer excited state in which at least one ligand of the complex is unstable and decomposes, then the remaining parts of the complex are unstable and spontaneously decompose. In its broad aspects, however, this invention is not to be construed to be limited to these reaction mechanisms.

During exposure, the atmosphere and pressure, both total and partial, under which the deposited film is at least partially converted through exposure to an energy source may be important process variables. Normally, it is convenient and economical for the atmosphere to be air, but it may be preferable to change the composition of the atmosphere present during at least partial conversion. One reason for this is to increase the transmission of the exposing light, if short wavelength light is used, because such light may be attenuated by air. Another reason to change the composition of the atmosphere may be to alter the composition or properties of the product film. For example, the exposure of a copper complex results in the formation of a copper oxide in air or oxygen atmospheres. By virtually eliminating oxygen from the atmosphere, a film comprising primarily reduced copper species may be formed. In another example, a partial conversion or conversion step is preferably performed in the presence of oxygen, if the converted precursor is to be a dielectric film, or in the presence of a reducing gas, such as hydrogen, if the converted precursor is to be a metallic film. Additionally and optionally, the amount of oxygen in the film may be further altered by modifying the humidity of the atmosphere in which conversion takes place.

Completion of conversion of the precursor material may be the last step in certain embodiments. In other embodiments, no post-exposure treatment of the exposed precursor material is required, but further patterning may be desirable. Alternatively, however, in certain embodiments an optional post-conversion processing step may be required.

In step 106 of FIG. 1, following at least partial conversion of the deposited precursor, the precursor film may optionally be treated by any of a variety of prior art methods before removing at least a portion of the unconverted precursor layer. These methods include, but are not limited to, exposure to a specific atmosphere, e.g., oxidizing or reducing, ion implantation, microwave treatment and electron beam treatment. If the at least partial converted area(s) may serve as electroless plating nucleation sites relative to the unconverted area(s) of the precursor, then an optional plating step may be used at this stage. If the film is a blanket film, and no further patterning or treatment is necessary, the film deposition process is terminated at this point.

In step 107 of FIG. 1, following exposure and/or post-exposure treatment, unexposed regions of the deposited film, or a portion thereof, may then be removed by the application of a film-removing agent. For example, a film-removing agent may comprise a developer composition that may be applied as a liquid or a solution in a puddle development or immersion wet development process. Alternately, a dry development process analogous to dry patterning steps conventionally employed by the semiconductor industry may be employed as a film-removing agent. Preferred film-removal methods include spray development, puddle development, and immersion wet development.

The developer should be formulated and/or used under conditions such that a solubility difference exists between exposed and unexposed regions of the film. This solubility difference is used to preferentially remove select regions of the film such that certain regions of the film are substantially removed by the developer while other regions are left substantially intact. For example, in a process in which regions that have been exposed to incident energy are desired to remain on the substrate, use of the casting solvent to develop the film after exposure to incident radiation is too aggressive. A dilute solution of the casting solvent in another liquid in which (a) the casting solvent is miscible, (b) unexposed regions of the film are sparingly (but not necessarily completely) soluble, and (c) exposed regions of the film are substantially insoluble, provides for an improved development process.

To further illustrate, in one preferred embodiment of the invention an amorphous film may be cast from a ketone solution. However, in contrast, the development process is more effective using alcohol as the majority component, versus using ketone alone as a developer, or a ketone-rich mixture of alcohol and the ketone, i.e., a mixture with greater than 50 vol. % ketone. For instance, 10:1 (vol/vol) isopropanol (IPA): methyl isobutyl ketone (MIBK) solution is a more effective developer for BaₓSr_{y}Ti_{z}O₃ (“BST”) than MIBK alone or 1:1 (vol/vol) IPA:MIBK. The 20:1 mixture, in turn, is more effective than 10:1 IPA:MIBK. However, both of the 10:1 and 20:1 solutions are more effective than a solution of 40:1 (vol/vol) IPA:MIBK. Furthermore, the relative effectiveness of these solutions depends heavily on other processes employed in the formation of the patterned film including, for example, the type and energy of incident radiation and the temperature of the substrate during coating and patterning. Liquid and/or solution-based developers may be physically applied in a fashion analogous to development methods employed with photoresist-based processes, for example, those discussed above. For many embodiments, no further processing is necessary following this step 107.

In 108 of FIG. 1, however, optional treatment of the patterned film following development may be desirable. If the precursor has yet to be substantially fully converted, for example, the precursor film is optionally subjected to an energy source such that the precursor is substantially fully converted. The entire film or selected regions of the precursor film may be exposed to a source of energy. The energy source can be an energy source that is the same as or different from any energy source previously employed. For example, the energy source may be a light source of a specific wavelength, a coherent light source of a specific wavelength, a broadband light source, an electron beam source, and/or an ion beam source. In certain embodiments of the invention, the energy source, or at least a portion of the energy source, is a light source directed through an optical mask used to define an image on the surface, as discussed above. However, the energy source need not be directed through a mask. For example, it may not be necessary to pattern the material during this conversion step 107, because the precursor may already be patterned. Therefore, a flood or blanket exposure may be used as the converting means. Preferred energy sources include light, electron beam, and ion beam. As discussed above for the case of partial conversion and as is also applicable here, the atmospheric conditions under which the deposited film is converted, such as atmosphere composition, pressure, both total and partial, and humidity, may be important process variables. During conversion, these variables may be the same as or different from their settings used in any preceding partial conversion step.

It is recognized that some shrinkage of the film may occur during the process of partially converting and/or substantially fully converting the precursor film to the film of the desired material. Therefore, the thickness of the film of the desired material is often less than the thickness of the unconverted precursor film. This change in thickness is an important feature of the invention, conferring useful properties to the film of desired material. For example, formation of extremely thin films is advantageous with respect to maximizing capacitance, while at the same time the formation of such thin films is challenging from a manufacturing standpoint. Therefore, the process of the invention provides not only the capability to apply relatively thicker cast films, conferring greater manufacturing ease, but also provides relatively thinner films of the desired at least partially converted precursor material, thereby conferring improved properties to the film of the desired material. The shrinkage properties of the deposited film may be controlled and tuned to target parameters by judicious manipulation of many of the aforementioned process variables including: the selection of the precursor, the selection and quantity of the solvent, the identity of precursor additives, the thickness of the precursor film as determined by the deposition process, the use of thermal treatments before, during and after the patterning of the film, and the development of the exposed film. The process of the invention allows for precise thickness control of desired films ranging in total thickness from the Angstrom range through the micrometer range.

It is further recognized that different ferroelectric properties, such as an increased capacitance or remnant polarization, for example, may be desirable. In these embodiments, an increase in capacitance and remnant polarization is frequently observed with moderate-temperature annealing of the converted film. Moderate temperature, are defined as temperatures of approximately 200° C. or less. In a preferred embodiment, the converted film is annealed at a temperature between 100° C. and 200° C., for between 5 and 30 minutes. It is important to recognize that such annealing does not result in an increase in long-range order in the film under these conditions. The annealed film remains amorphous. Optionally, if desired, the films may be heated at higher temperatures to effect at least partial crystallization.

Additionally, the present invention is also amenable to optimization methods typically used for crystalline ferroelectric materials. One method is through the preparation of materials of different chemical compositions by addition or substitution of constituents to the precursor material. In some cases it may also be possible to modify the initially deposited film by, for example, treatment with fluorine. Examples of modified materials include, but are not limited to, (BaₓSr₍₁₋ₓ₎)TiO₃ (0.5<x<1), which is substituted BaTiO₃ and Pb_{0.98}(La₍₁₋ₓ₎Liₓ)_{0.02}(Zr_{0.55}Ti_{0.45})O₃, (0.1<x<0.7), which is substituted PbTiO₃. Additives which are useful for substitution include, for instance, Pb, Ba, Nb, Ta, W, Bi, Sb, Sr, Zr, La, Li, Ca, Ce, Y, Fe, Al, Cu, Na, Cr, Mn, Mg, and Ni. It should be understood that included within the above examples are materials such as (Na_{0.5}Bi_{0.5})TiO₃ which result from complete substitution for Ba in BaTiO₃, for example. More generally, the films produced should substantially comply with the formula (A₁₋ₓ)(D_{1-y})(Eᵢ)_{c}_{ᵢ}O₃, where A, B, and E are metals, and where the values of x and y are substantially constrained by the relationship

$$2 x + 4 y = {\sum }_{i} {v}_{i} {c}_{i} ,$$

where vᵢ is the valence of the ith element. Subjecting x and y to these constraints results in the formation of amorphous films with a non-centrosymmetric structure, which is often desirable for metal and metal oxide films having ferroelectric properties. Another method for modifying the ferroelectric film is through the addition of nanoparticulate metals, such as Ag, for instance. The method used for such an addition is similar to that disclosed in U.S. Pat. No. 6,458,431 to Hill, et. al., the disclosure of which is incorporated herein by reference in its entirety. Nanoparticulate metals amenable to this process include, but are not limited to, Ag, Cu, Pt, Ni, Au, Pd, Ru, and Rh.

These variables are intended as examples and are not to be considered exhaustive lists of the variables that may be manipulated to affect the properties of the resulting film. More specific aspects and embodiments of the present invention are described in detail below.

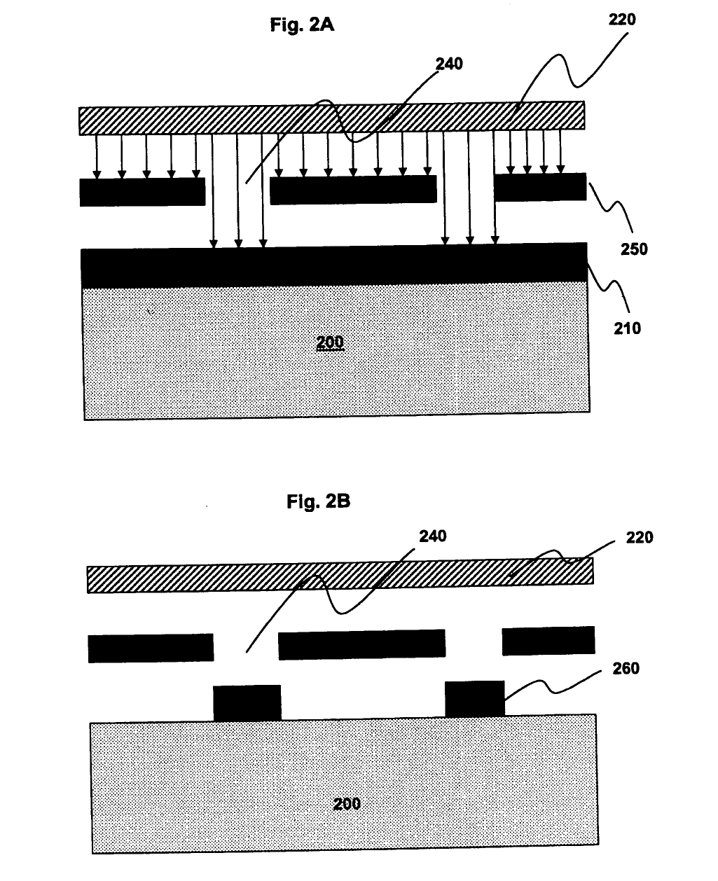

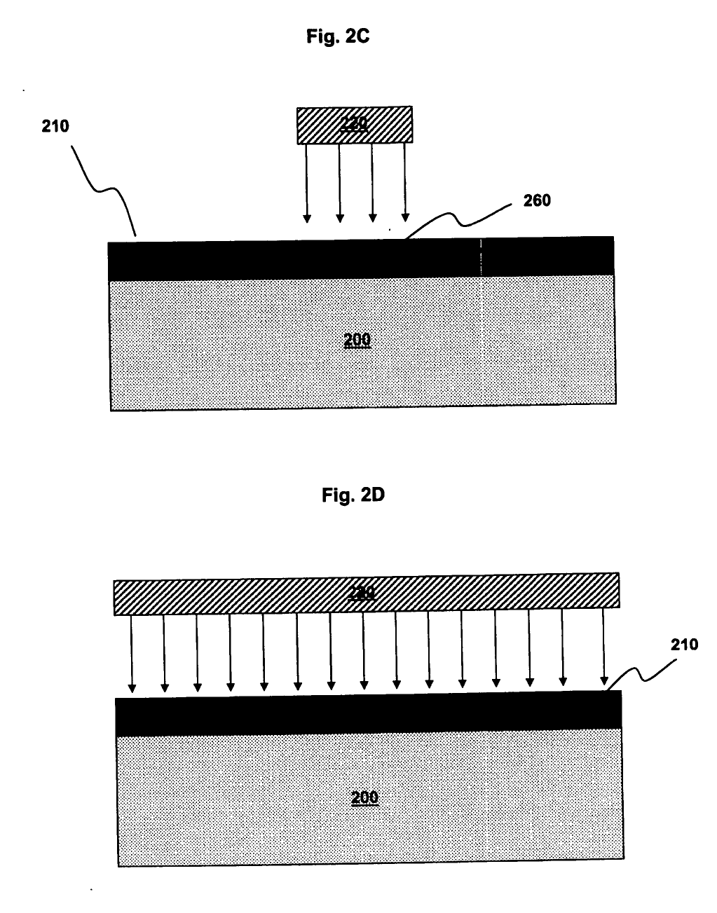

FIGS. 2A and B are schematic cross-sectional views of a substrate covered with precursor material and converted precursor material, respectively, wherein the precursor material is exposed to an energy source that will convert the precursor material. Turning to FIG. 2A, in certain embodiments of the invention, the energy source is a light source 220 that omits light that is directed through an optical mask 250 used to define an image on the surface of the precursor material 210. The mask 250 consists of substantially transparent regions 240 and substantially opaque or light absorbing 230 regions. The mask 250 may also include an optical enhancing feature such as a phase shift technology (not shown). FIG. 2B illustrates that, following conversion of the precursor material 210, the non-converted precursor material may be removed. This leaves a patterned film of converted precursor material 260.

FIG. 2C is a schematic cross-sectional view of a substrate covered with precursor material being directly patterned using a maskless process. In this embodiment, a layer of precursor material 210 is deposited on a substrate 200. Following (optional) post-deposition treatment, the unconverted precursor material is irradiated using an energy source 220. However, rather than using a mask to form a pattern on the precursor material, the energy source forms a patterned film 260 directly in the precursor material. Certain light sources 220, such as x-ray or laser, for example, may be able to directly pattern the image onto the surface using a mechanism that directionally applies the energy, through a mechanical, electromagnetic, or optical means (not shown), for instance. Once the pattern 260 is formed, unconverted precursor material 270 may be removed.

FIG. 2D is a schematic cross-sectional view of a substrate covered with precursor material being converted through blanket exposure to an energy source. While the above patterned-film embodiments may be preferred, it should be understood that the current invention is not limited to converting precursor materials to form patterned films. If it is not necessary to pattern the precursor material 210, a flood or blanket energy exposure 220 may be used. Such an exposure will result in the formation of an unpatterned, blanket film.

In a variation of the above embodiments described in connection with FIGS. 2A-D, the atmosphere and pressure, both total and partial, under which the deposited film is at least partially converted through exposure to an energy source may be important process variables. Normally, it is convenient and economical for the atmosphere to be air, but it may be preferable to change the composition of the atmosphere present during at least partial conversion. One reason for this is to increase the transmission of the exposing light, if short wavelength light is used, because such light may be attenuated by air. Another reason to change the composition of the atmosphere may be to alter the composition or properties of the product film. For example, the exposure of a copper complex results in the formation of a copper oxide in air or oxygen atmospheres. By virtually eliminating oxygen from the atmosphere, a film comprising primarily reduced copper species may be formed. In another example, a partial conversion or conversion step is preferably performed in the presence of oxygen, if the converted precursor is to be a dielectric film, or in the presence of a reducing gas, such as hydrogen, if the converted precursor is to be a metallic film. Additionally and optionally, the amount of oxygen in the film may be further altered by modifying the humidity of the atmosphere in which conversion takes place.

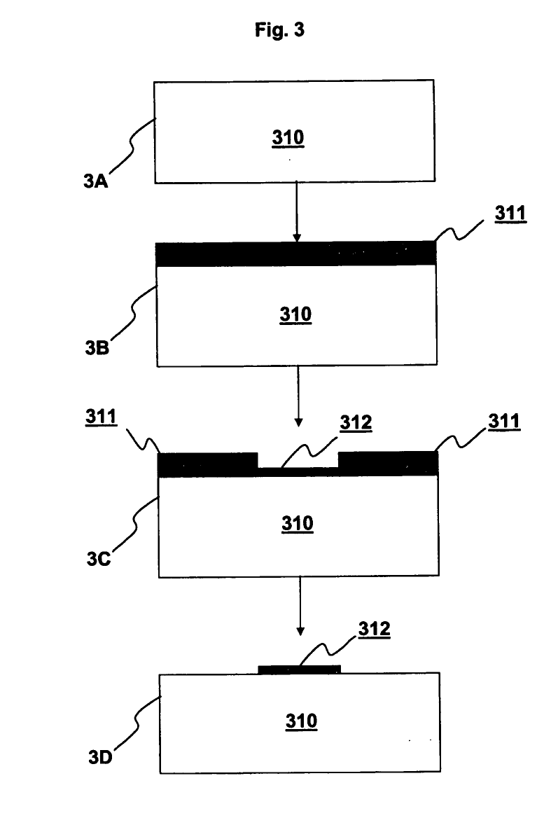

FIG. 3 illustrates room temperature deposition of a pattered ferroelectric film according to one embodiment of the present invention. FIG. 3A illustrates that the deposition process begins with a substrate 310. The substrate 310 may be, for example, a silicon wafer that has been coated with an organic layer. In step 3B, unconverted precursor material 311 is applied to the substrate 310. In step 3C, an energy source, such as light in the photochemical metal organic deposition process, is applied to at least one selected portion of unconverted precursor material 311 to form a converted precursor layer 312. In step 3D, a film-removing agent, such as a developer composition, is used to remove at least a portion and, preferably, substantially all, of the unconverted precursor layer 311, leaving the converted precursor 312 intact, thereby forming a film which is substantially ferromagnetic on the substrate 310.

Alternately, in step 3C of FIG. 3, an energy source, such as light or thermal or heat treatment, may be applied to at least one selected portion of unconverted precursor 311 to form a partially converted precursor layer 312. In step 3D, a film-removing agent, such as a developer composition, is used to remove at least a portion and, preferably, substantially all, of the unconverted precursor layer 311, leaving the partially converted precursor 312 intact. An energy source, such as light can then be used on at least a portion of the partially converted precursor to substantially convert that portion, thereby forming a patterned ferromagnetic film. The energy source used to partially convert the precursor layer can be the same as or different from the energy source used to substantially convert the film. FIG. 3 demonstrates the economy of steps in forming a patterned ferroelectric film by the process of the present invention.

In a preferred embodiment of the invention, a ferroelectric film is used to form a decoupling capacitive structure within the interconnect levels of an advanced interconnect semiconductor device. First, a modified silicon substrate is coated and directly imaged by the present process with an appropriate precursor solution. Following imaging, the film is developed and any unconverted precursor material is removed. The film exhibits ferroelectric properties as deposited thus, at most, a mild annealing step is required. This is surprising, because room-temperature ferroelectric films are rarely realized by any process, and have not previously been realized by a process where direct patterning is available. Advantages implicit in this embodiment include the ability for direct imaging, thereby eliminating many other process steps, and the use of ambient temperatures and pressures not otherwise available in the assembly of such advanced interconnects. This reduces the time and cost associated with the prior art annealing method. Furthermore, these films are stable at elevated temperatures, therefore they are able to withstand subsequent above room-temperature processing steps.

A further preferred embodiment of the invention envisions the use of precursor films to pattern memory storage elements as ferroelectric memory storage nodes (“FeRAM”). Again, advantages implicit in this embodiment include the ability for direct imaging, thereby eliminating many other process steps, and the use of ambient temperatures and pressures not otherwise available in the assembly of such memory devices.

Yet another preferred embodiment of the invention envisions the formation of gate dielectric materials at the front end of semiconductor manufacture. This becomes important as advanced silicon-based devices transition from silicon dioxide as the preferred gate dielectric material, to new materials having a higher dielectric constant. Ferroelectric materials often possess a relatively high dielectric constant, and as such, are of great interest to the microelectronics industry. These higher dielectric constant materials allow the gate dielectric to be made thicker, relative to silicon dioxide, for equivalent electrical properties. This greater thickness allows for greater ease of manufacture and minimized quantum tunneling effects through the gate. Additionally, the cost savings inherent in the lower processing temperatures and less stringent vacuum processing requirements of the present invention is highly significant when applied to front end of the line (“FEOL”) semiconductor processing. Other embodiments include, but are not limited to, microwave to millimeter wave devices, such as phase shifters, delay lines, voltage and frequency tunable microwave devices, integrated passives, micro-amours, infrared sensors, dielectric resonators, RF filters, varistor-capacitor devices, phased array antennas, frequency agile filters and tunable high-Q resonators. A wide variety of high dielectric constant materials are amenable to the process of the invention, including but not limited to BaSr_{y}Ti_{z}O₃ (“BST”), BaTiO₃, SrTiO₃, PbTiO₃, PbₓZr_{y}Ti_{z}O₃ (“PZT”), (Pb, La) (Zr, Ti)O₃ (“PLZT”), (Pb, La)TiO₃ (“PLT”), LiNbO₃, Ta₂O₅, SrBi₂Ta₂O₉, Al₂O₃, TiO₂, ZrO₂ and HfO₂.

The following examples further illustrate certain embodiments of the present invention. These examples are provided solely for illustrative purposes and in no way limit the scope of the present invention.

### EXAMPLE 1

Films deposited in accordance with the present method exhibit ferroelectric properties without the need for high-temperature annealing. To illustrate this, precursor material was deposited on silicon wafers by dissolving lead 2-ethylhexanoate, zirconium 2-ethylhexanoate and titanium isopropoxide in hexane solvent to form an 86 wt. % solution, and spin-coating the wafer. The film was then exposed to 254 nm UV light to convert the film. Reaction progress was monitored using Fourier Transform Infrared Spectroscopy (FTIR). Degree of conversion of the precursor layer was determined by observing the change of the C—H stretch in the region of 2900 cm⁻¹, as well as the C—O absorption bands between 1700-1200 cm⁻¹. Photolysis was considered complete when the C—H and C—O stretching vibrations were no longer detectable. The film thus deposited was approximately 420 Å thick, and was comprised of PbZr₁₋ₓTiₓO₃. After photolysis of the first deposited precursor layer was complete, a second layer of precursor film was deposited on top of the previously converted first layer, using precursor solution identical to that used for the first layer. The second layer was then subjected to exhaustive photolysis. When conversion of the second layer was complete, the process was repeated, for a total of six layers. The final film thickness was approximately 2500 Å. Electrodes 500 μm in diameter were formed on the resulting film by sputter deposition of a 1500 Å thick platinum target, and the capacitance and the remnant polarization of the film measured. Before anneal, the film exhibited a capacitance of about 3.0 pF, without hysteric behavior and with no remnant polarization. However, after annealing, capacitances of 227 and 197 pF, and remnant polarizations of 0.6 and 0.7 μC/cm² were obtained with 100 and 200° C. annealed film, respectively. The capacitance measurements show hysteric behavior. Hysteric behavior in the capacitance measurement and the presence of remnant polarization typically indicate ferroelectric behavior. The resulting measurement thus indicated that the deposited and annealed films were ferroelectric. This is despite the fact that the film was still amorphous. No evidence was found of any long-range order in the film. While only six layers were deposited here, this repetitive layer deposition process can be repeated for any number of cycles, the only constraint being the increase in surface roughness. In this way, ferroelectric films up to about 5000 Å may be deposited.

Although the present invention has been described with particular reference to its preferred embodiments, it should be understood that these embodiments are illustrative and that the invention may be modified and practiced in different but equivalent manners apparent to those skilled in the art having the benefit of the teachings herein. It is therefore evident that the particular embodiments disclosed above may be altered or modified in ways that such variations are considered within the scope and spirit of the invention. Therefore, the scope of the invention should not be limited by the specific disclosure herein, but only by the appended claims.

What is claimed is:

1. A method for making a film of ferroelectric material on a substrate, comprising:
depositing an amorphous film comprising at least one precursor material on a surface of a substrate; and
irradiating the amorphous film to produce a converted precursor comprising ferroelectric material.

2. The method of claim 1 wherein the ferroelectric material comprises (A₁₋ₓ)(D_{1-y})(Eᵢ)_{c}_{ᵢ}O₃, where A, D and E are metals, where x and y range from 0 to 1.0; and where the values of x and y substantially comply with the relation
$$2 x + 4 y = {\sum }_{i} {v}_{i} {c}_{i} ,$$
where vᵢ is the valence of the ith element.

3. The method of claim 2 wherein the ferroelectric material comprises barium strontium titanate.

4. The method of claim 1 wherein the ferroelectric material comprises (A₁₋ₓ)(D_{1-y})(Eᵢ)_{c}_{ᵢ}O₃, where x and y range from 0 to 1.0; the substitutions A, D and Eᵢ are chosen from the group consisting of Pb, Nb, Ta, W, Bi, Sb, Sr, Zr, La, Li, Ca, Ce, Y, Fe, Al, Cu, Na, Cr, Mn, Mg, and Ni; and the values of x and y substantially comply with the relation
$$2 x + 4 y = {\sum }_{i} {v}_{i} {c}_{i} ,$$
where vᵢ is the valence of the ith element.

5. The method of claim 4 wherein the ferroelectric material comprises lead zirconium titanate.

6. The method of claim 1 wherein the at least one precursor material comprises lead (II)2-ethylhexanoate, zirconium(IV) 2-ethylhexanoate, and Ti(bis(acetylacetonate)di(isopropoxide)).

7. The method of claim 1 wherein the at least one precursor material comprises barium 2-ethylhexanoate, strontium 2-ethylhexanoate, and titanium (acac)₂(isopropoxide)₂.

8. The method of claim 1 wherein the irradiating comprises irradiating the amorphous film with electromagnetic radiation.

9. The method of claim 1 wherein the irradiating comprises irradiating the amorphous film with ultraviolet light.

10. The method of claim 1 wherein the irradiating comprises irradiating the amorphous film with laser light.

11. The method of claim 1 wherein the irradiating causes a substantially thermal reaction in the amorphous film.

12. The method of claim 1 wherein the irradiating comprises visible light.

13. The method of claim 1 wherein the irradiating comprises irradiating the amorphous film with an ion beam.

14. The method of claim 1 wherein the irradiating comprises irradiating the amorphous film with an electron beam.

15. The method of claim 1 wherein the irradiating comprises exposing the amorphous film to a plasma.

16. The method of claim 1 wherein the irradiating is done in a controlled atmosphere.

17. The method of claim 16 wherein the controlled atmosphere comprises nitrogen.

18. The method of claim 16 wherein the controlled atmosphere comprises a vacuum.

19. The method of claim 16 wherein the controlled atmosphere comprises oxygen.

20. The method of claim 16 wherein the controlled atmosphere comprises air.

21. The method of claim 20 wherein the controlled atmosphere further comprises water.

22. The method of claim 1 further comprising removing unirradiated precursor material from the substrate after irradiating the film.

23. The method of claim 1 where the substrate is maintained at a temperature substantially below 100° C.

24. A method for making a film of ferroelectric material on a substrate, comprising:
depositing an amorphous film comprising at least one precursor material of a type known to form a crystalline ferroelectric material on a surface of a substrate; and
irradiating the amorphous film to produce a converted precursor comprising ferroelectric material.

25. A method for making a patterned film of ferroelectric material on a substrate, comprising:
depositing an amorphous film comprising at least one precursor material on a surface of a substrate;
irradiating the precursor material to produce a partially irradiated film comprising ferroelectric material; and
developing the film to substantially remove unirradiated precursor material.

26. The method of claim 25 wherein the substrate is maintained at temperature substantially below 100° C.

27. The method of claim 25 wherein the irradiating is done using a mask.

28. The method of claim 25 wherein the ferroelectric material comprises barium strontium titanate.

29. The method of claim 25 wherein the ferroelectric material comprises lead zirconium titanate.

30. A method for making a film of ferroelectric material on a substrate, comprising:
depositing an amorphous film comprising at least one precursor on a surface of a substrate;
irradiating the precursor to produce an irradiated film; and
heating the irradiated film to produce a ferroelectric material.

31. The method of claim 30 wherein said heating comprises a temperature 200° C. or less.

32. The method of claim 30 wherein the heat treatment causes at least partial crystallization of the irradiated film 32.

33. The method of claim 32 wherein the heating is further done in a controlled atmosphere.

34. The method of claim 33 wherein the controlled atmosphere is selected from the group consisting of nitrogen, oxygen, air, vacuum or water, and combinations thereof.

35. The method of claim 33 wherein the ferroelectric material comprises barium strontium titanate.

36. A non-crystalline ferroelectric film in an electronic device, formed using the method comprising:
depositing an amorphous film comprising at least one precursor material on a surface of a substrate; and
irradiating the amorphous film to produce a converted precursor comprising ferroelectric material.

37. The non-crystalline ferroelectric film in an electronic device of claim 36 wherein the ferroelectric material comprises (A₁₋ₓ)(D_{1-y})(Eᵢ)_{c}_{ᵢ}O₃, where A, D and E are metals, where x and y range from 0 to 1.0; and where the values of x and y substantially comply with the relation
$$2 x + 4 y = {\sum }_{i} {v}_{i} {c}_{i} ,$$
where vᵢ is the valence of the ith element.

38. The non-crystalline ferroelectric film in an electronic device of claim 37, wherein the ferroelectric material comprises barium strontium titanate.

39. The non-crystalline ferroelectric film in an electronic device of claim 36 wherein the ferroelectric material comprises (A₁₋ₓ)(D_{1-y})(Eᵢ)_{c}_{ᵢ}O₃, where x and y range from 0 to 1.0; the substitutions A, D and Eᵢ are chosen from the group consisting of Pb, Nb, Ta, W, Bi, Sb, Sr, Zr, La, Li, Ca, Ce, Y, Fe, Al, Cu, Na, Cr, Mn, Mg, and Ni; and the values of x and y substantially comply with the relation
$$2 x + 4 y = {\sum }_{i} {v}_{i} {c}_{i} ,$$
where vᵢ is the valence of the ith element.

40. The non-crystalline ferroelectric film in an electronic device of claim 39 wherein the ferroelectric material comprises lead zirconium titanate.

41. The non-crystalline ferroelectric film in an electronic device of claim 36 wherein the at least one precursor material comprises lead (II)2-ethylhexanoate, zirconium(IV) 2-ethylhexanoate, and Ti(bis(acetylacetonate)di(isopropoxide)).

42. The non-crystalline ferroelectric film in an electronic device of claim 36 wherein the at least one precursor material comprises barium 2-ethylhexanoate, strontium 2-ethylhexanoate, and titanium (acac)₂(isopropoxide)₂.

43. A film in an electronic device, comprising:
a non-crystalline ferroelectric material.

44. The film of claim 43 wherein the ferroelectric material comprises (A₁₋ₓ)(D_{1-y})(Eᵢ)_{c}_{ᵢ}O₃, where A, D and E are metals, where x and y range from 0 to 1.0; and where the values of x and y substantially comply with the relation
$$2 x + 4 y = {\sum }_{i} {v}_{i} {c}_{i} ,$$
where vᵢ is the valence of the ith element.

45. The film of claim 43, wherein the ferroelectric material comprises barium strontium titanate.

46. The film of claim 43 wherein the ferroelectric material comprises (A₁₋ₓ)(D_{1-y})(Eᵢ)_{c}_{ᵢ}O₃, where x and y range from 0 to 1.0; the substitutions A, D and Eᵢ are chosen from the group consisting of Pb, Nb, Ta, W, Bi, Sb, Sr, Zr, La, Li, Ca, Ce, Y, Fe, Al, Cu, Na, Cr, Mn, Mg, and Ni; and the values of x and y substantially comply with the relation
$$2 x + 4 y = {\sum }_{i} {v}_{i} {c}_{i} ,$$
where vᵢ is the valence of the ith element.

47. The film of claim 43 wherein the ferroelectric material comprises lead zirconium titanate.
